(19) United States
(12) Patent Application Publication
(10) Pub. No.: US 2004/0007053 A1
(43) Pub. Date: Jan. 15, 2004

(54) SPM sensor and process for producing same

(76) Inventors: Stefan Lutter, Neuchatel (CH); Manfred Detterbeck, Neuchatel (CH); Theo Hartmann, (US)

Correspondence Address: BACHMAN & LAPOINTE, P.C., 900 CHAPEL STREET, SUITE 1201, NEW HAVEN, CT, 06510, US

(21) Appl. No.: 10/400,052

(22) Filed: Mar. 26, 2003

(30) Foreign Application Priority Data
May 3, 2002 (EP) 02 009 921.4

(51) Int. Cl. G12B 21/02; G01R 3/00

(52) U.S. Cl. 73/105; 29/595

(57) ABSTRACT

An SPM sensor having a cantilever, a holding element at one end of the cantilever and a sensor tip at the other end of the cantilever, wherein the holding element is made from a photoresist and the cantilever and/or the tip are made from another material. The photoresist is preferably SU-8, and the other material for the cantilever and/or the tip is preferably silicon, a silicon compound, metals and mixtures thereof. The production of a frame having a plurality of the SPM sensors, wherein both the frame and the holders for the individual SPM sensors and at least the holding element consist of SU-8. The process allows for inexpensive production of the SPM sensors, the sensors being supplied to the user in a frame from which he can detach the sensors.

### BACKGROUND OF THE INVENTION

The present invention relates to an SPM sensor and to a process for producing sensors of this type.

Scanning probe microscopes (SPMs) are generally known and are used in practice to scan the surface of specimens using fine sensors of atomic resolution. SPMs include what are known as STMs (Scanning Tunneling Microscopes) and AFMs (Atomic Force Microscopes), which are likewise generally known.

All these known microscopes use sensors which comprise a micro-scale bending bar, referred to below as the cantilever, which at one end has a holding element and at the other end has a sensor tip, by means of which the specimen is scanned.

It is known from U.S. Pat. No. 6,291,140 (incorporated herein by reference) to produce a sensor of this type entirely from a photoresist, in particular SU-8. Although the process described in this publication does allow series production of sensors of this type, they have to be detached from the substrate individually.

It is furthermore generally known to produce sensors, and in particular the tip and also the cantilever, from silicon, silicon compounds or metals. The production of sensors from SU-8 represents a particularly low-cost process. However, there continues to be a demand for sensors with a tip made from a material other than SU-8.

Accordingly, it is an object of the present invention to provide a novel sensor which can be produced at low cost.

### SUMMARY OF THE INVENTION

The foregoing object is achieved by providing a SPM sensor comprising (I) a cantilever (9), a holding element (10) at one end of the cantilever (9) and a sensor tip (8) at the other end of the cantilever (9), wherein the holding element (10) is made from a photoresist and one of the cantilever (9) and the tip (8) is made from another material. The invention further comprises a process for producing the SPM sensor which comprises (II) the following steps: (a) forming an incision (4) in a substrate (1); (b) depositing a layer (6) selected from the group consisting of silicon, silicon compound, metal and mixtures thereof, which fills the incision (4) and covers at least a part of the substrate (1); (c) photolithographic patterning of the layer (6) to form one of the cantilever (9) and the tip; (d) applying a photoresist layer to form the holding element (10); and (e) detaching the SPM sensor (13) from the substrate (1).

According to the present invention, the holding element is made from a photoresist and the cantilever and/or the tip is/are made from another material. The result is a hybrid sensor which consists of different materials and can be produced at particularly low cost, since a large part of the sensor is made from a photoresist, preferably SU-8. According to a preferred embodiment, the cantilever and/or the tip are made from silicon, a silicon compound, metals or a combination thereof. Although the adhesion of a photoresist, in particular of SU-8, to silicon, silicon nitride or metals is known to be very poor, it has been possible to produce combined SPM sensors of this type. To do this, the adhesion between the materials has been improved. This can be achieved, for example, by widening the cantilever structure below the holding element, by using an adhesion promoter which is based on epoxy resin, or by increasing the surface area by patterning the cantilever in three dimensions, so that the photoresist can link to the metal or silicon nitride in the vertical direction as well.

To simplify production of these SPM sensors, according to a further refinement of the invention they are arranged in an SPM sensor assembly having a multiplicity of further SPM sensors, which are connected via at least one holder to a frame made from photoresist, preferably SU-8. All the SPM sensors are detached from the silicon below them in the known way and can be broken off from the holding frame as required.

According to the process, a sensor of this type is produced in the following way:

First of all, a tip-like trench is formed in a substrate, for example silicon. Then, a layer of silicon, a silicon compound or a metal, for example chromium or aluminum, or a combination of these materials is deposited on the substrate, filling the tip-like trench and covering at least part of the substrate. This is followed by photolithographic patterning of the layer in order to form the cantilever and the tip, with subsequent removal of the photoresist, the application of a photoresist layer to form the holding element and then detachment of the SPM sensor from the substrate.

The application of a photoresist layer to form the holding element can additionally be used to produce a frame structure and holders as connection to the holding element.

It is preferable for a sacrificial layer to be applied to the substrate before the layer for filling the tip-like trench is deposited, in order to improve the separation of the sensor from the substrate.

In another embodiment of the process, the cantilever may also consist of photoresist, in particular SU-8. Photoresist SU-8 is an epoxy-based, negative tone UV resist system with excellent sensitivity designed specifically for ultra-thick, high aspect-ratio microsystems.

Therefore, the invention provides a high-performance yet simple process for producing SPM sensors which, on account of the use of the inexpensive photoresist, in particular SU-8, and the connection of the individual sensors, allows the SPM sensors to be rapidly detached and passed on to third parties. The template for the tip is reusable in a known way, and it is merely necessary for the materials for new sensors to be constantly reapplied to this surface.

### BRIEF DESCRIPTION OF THE DRAWINGS

The invention is explained in more detail below with reference to exemplary embodiments, wherein:

FIGS. 1-11 show sectional illustrations, and in some cases plan views, of the process for producing an SPM hybrid sensor of this type in an SPM sensor assembly; and

FIGS. 12 and 13 show a plan view of two different variants of SPM sensors with particular measures for improving the adhesion.

### DETAILED DESCRIPTION

In the exemplary embodiments, the frame and therefore the SPM sensor assembly always consists of the photoresist SU-8. Where the text refers to photolithographic patterning, this is always understood to mean the measures, carried out in a known way, of applying a photoresist, exposing the photoresist in accordance with a mask, developing the photoresist and removing the photoresist.

In general, the production is carried out in such a manner that, using a substrate, for example silicon, trenches are produced, with the aid of which it is possible to mold microtips which are suitable for use as an SPM sensor. The microtips are molded as described in EP 990 195. It is optionally also possible for a sacrificial layer, for example aluminum or silicon oxide, to be applied to the substrate. The deposition of the material for production of the cantilever and of the tip then takes place. The cantilever is then photolithographically patterned out of the material which has been deposited, so that the molded tip is located at one end of the cantilever. Then, the SU-8 photoresist is applied, and after that the holding element, the frame and the holders, which connect the holding element and the frame to one another, are patterned. The holding elements are positioned in such a way that the cantilever with the molded tip projects beyond the holding element. Next, the substrate/sacrificial layer is removed in an etching step, by means of which the substrate/sacrificial layer can be etched selectively with respect to the photoresist SU-8 and the material of which the cantilever and the tip consist. What remains is an SPM sensor assembly having a multiplicity of SPM sensors with a frame, holders and holding elements made from the photoresist SU-8, to which the cantilevers with tip are secured. If a sacrificial layer is provided, this should also be removed and the SPM sensor assembly detached from it.

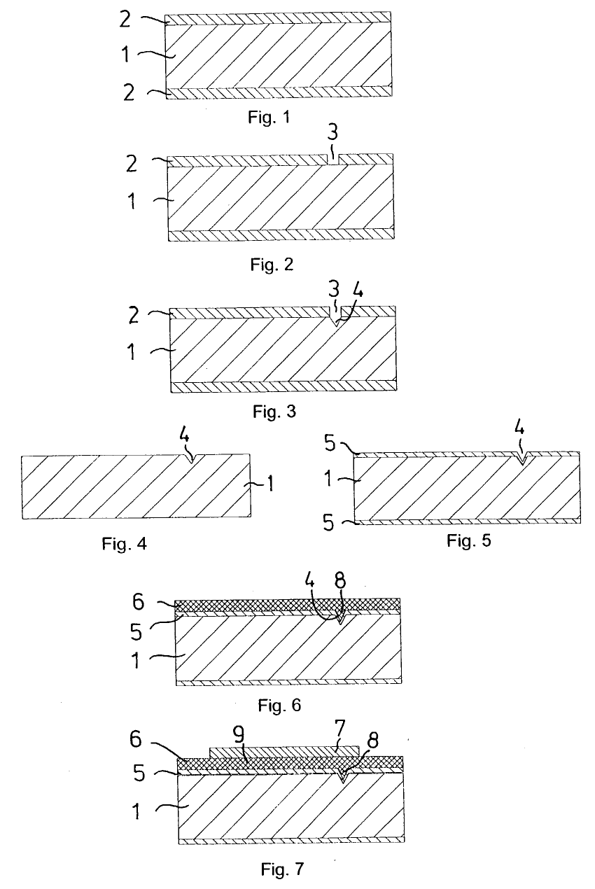

FIGS. 1 to 11 describe, by way of example, the production of an SPM sensor having a holding element made from SU-8 and with cantilever and tip made from silicon nitride. Accordingly, it is possible for a metal, for example aluminum or chromium or alternatively silicon, to be used instead of the silicon nitride.

The following figures only illustrate a silicon substrate 1; it will be clear to the person skilled in the art that this may be an entire wafer, on which a large number of sensors are processed simultaneously.

FIG. 1 shows, as starting material, silicon 1, to both sides of which a layer of silicon oxide 2 has been applied.

Next, the oxide layer is patterned in the usual way by application of a photoresist, exposure of the photoresist, developing of the photoresist, etching of the oxide layer, for example using hydrofluoric acid (HF) and removal of the photoresist, so that, as shown in FIG. 2, an opening 3 for the production of a trench 4, which is illustrated in FIG. 3, is produced in the oxide layer 2. The trench 4, which is illustrated in FIG. 3, in the silicon substrate is produced by means of an etching solution, for example potassium hydroxide solution (KOH). This trench 4 makes it possible to mold the tip which is required for the SPM sensor.

Next, the oxide layer 2 is removed from both sides by means of an etching solution, for example HF, as illustrated in FIG. 4.

To sharpen the trench 4, the silicon 1 is oxidized on both sides once again with a further silicon oxide layer 5 as sacrificial layer on both sides of the substrate 1 (FIG. 5). This process step is generally known and is customary for sharpening trenches.

Next, a silicon nitride layer 6 is applied to the silicon oxide layer 5 in order to fill the trench 4. The silicon nitride layer 6 can be applied, for example, using the PECVD (Plasma Enhanced Chemical Vapor Deposition) process. The layer thickness is 0.1 μm to 0.3 μm. The result is illustrated in FIG. 6.

FIG. 7 shows the structure with a photoresist 7 which has been applied to the silicon nitride layer 6, this structure being used to pattern that part of the silicon nitride layer below it which is subsequently to form the cantilever 9. The tip 8 in the trench 4 in the silicon oxide 5 also lies beneath the photoresist. The cantilever is patterned in the usual way by applying photoresist 7 to the entire wafer, exposing the photoresist 7 and developing the photoresist 7.

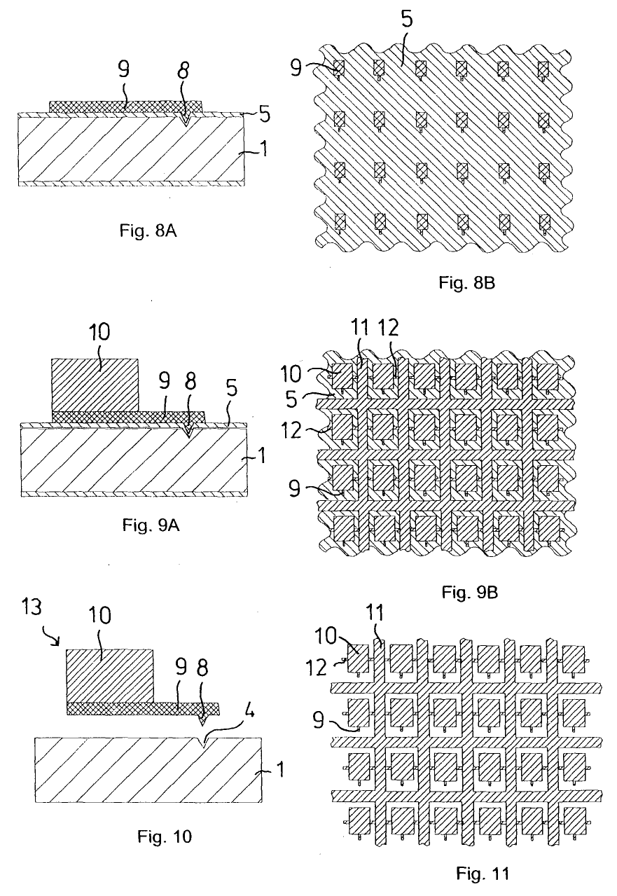

By means of dry-etching and subsequent removal of the photoresist 7, the silicon nitride layer 6 is patterned so that the cantilever 9 with the tip 8 is formed (FIG. 8A). FIG. 8B shows a plan view of the wafer having a large number of rectangular cantilevers 9 which have already been formed and have a wide area, to which the holding element is subsequently applied, and a narrow area, at the free end of which the tip is located.

Next, an SU-8 layer 10 is applied to the entire wafer and is photolithographically patterned in the usual way, and in the process the holding element 10 and the frame 11 with the holders 12 are patterned. FIG. 9A shows the result of this process step in section, and FIG. 9B shows the result of this process step in plan view. FIG. 9B also shows the frame 11 with the holders 12, likewise made of SU-8. The SU-8 layer of the holding element 10 and of the frame amounts to from 200 μm to 400 μm.

The finished SPM sensor 13 with the holding element 10 made from SU-8, the cantilever 9 and the tip 8 is then detached from the substrate 1 by removal of the sacrificial layer, in this case the oxide layer 5, by means of HF (FIG. 10).

FIG. 11 shows a plan view of the finished frame 11 with the holders 12 and the SPM sensors located therein in plan view, illustrating the holding element 10, the frame 11 and the holders 12 made from SU-8, as it can be sold. The individual SPM sensors 13 are separated from the frame 11 by being broken out of the frame 11.

After the SPM sensor 13 has been detached, the wafer with the prepared trenches 4 can be reused for the production of further SPM sensors.

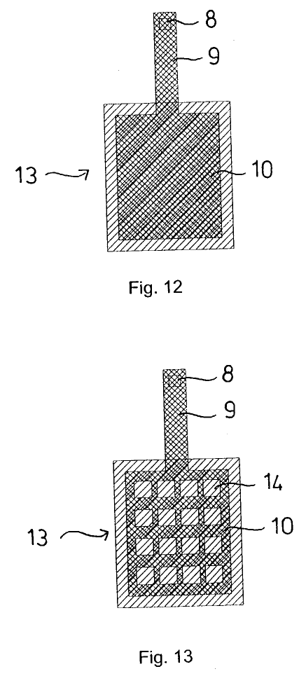

FIG. 12 shows a plan view of an SPM sensor 13 with the holding element 10, the cantilever 9 and the tip 8, in which, below the holding element 10, the cantilever structure, made in the present exemplary embodiment from silicon nitride, is widened, resulting in a larger surface area which improves the adhesion.

FIG. 13 shows how the surface area is increased, for example through the cantilever structure having openings 14, for example, so that the SU-8 photoresist links to the corresponding metal or the silicon nitride in the vertical direction as well.

Another possibility consists in using an adhesion promoter which is based on epoxy resin and in combining the individual proposed measures with one another, in order in this way to ensure sufficient adhesion.

The above text has described the production of an SPM sensor 13 with a holding element 10 made from SU-8. If only the tip 8 is to be produced from another material, only this tip is patterned, and after the application of the SU-8 layer the cantilever 9 is also produced by means of suitable masks. The thickness of the cantilever structure varies according to the material and cantilever property and may be between 0.1 μm and 6 μm.

It is to be understood that the invention is not limited to the illustrations described and shown herein, which are deemed to be merely illustrative of the best modes of carrying out the invention, and which are susceptible of modification of form, size, arrangement of parts and details of operation. The invention rather is intended to encompass all such modifications which are within its spirit and scope as defined by the claims.

1. An SPM sensor (13) comprising a cantilever (9), a holding element (10) at one end of the cantilever (9) and a sensor tip (8) at the other end of the cantilever (9), wherein the holding element (10) is made from a photoresist and one of the cantilever (9) and the tip (8) is made from another material.

2. The SPM sensor as claimed in claim 1, wherein another material is selected from the group consisting of silicon, a silicon compound, metals and mixtures thereof.

3. The SPM sensor as claimed in claim 1, including an SPM sensor assembly having a plurality of SPM sensors which are connected by means of at least one holder (12) to a frame (11) made from a photoresist.

4. The SPM sensor as claimed in claim 1, wherein the photoresist is SU-8.

5. A process for producing an SPM sensor comprising a holding element (10), cantilever (9) and a sensor tip (8), which projects out of the surface of the cantilever (9), at a free end of the cantilever, comprising the following steps:
(a) forming an incision (4) in a substrate (1);
(b) depositing a layer (6) selected from the group consisting of silicon, silicon compound, metals and mixtures thereof, which fills the incision (4) and covers at least a part of the substrate (1);
(c) photolithographic patterning of the layer (6) to form one of the cantilever (9) and the tip;
(d) applying a photoresist layer to form the holding element (10); and
(e) detaching the SPM sensor (13) from the substrate (1).

6. The process as claimed in claim 5, wherein a frame (11) with holders (12) as connections to the holding element (10) are additionally produced in step (d).

7. The process as claimed in claim 5 or 6, wherein prior to step (b) a sacrificial layer (5) is applied to the substrate (1), to improve the separation of the sensor (13) from the substrate (1).
